(19) United States
(12) Patent Application Publication
(10) Pub. No.: US 2016/0274155 A1
(43) Pub. Date: Sep. 22, 2016

(54) METHOD FOR ACQUIRING PARAMETERS OF DYNAMIC SIGNAL

(71) Applicants: STATE GRID CORPORATION OF CHINA (SGCC), Beijing (CN); STATE GRID CHONGQING ELECTRIC POWER CO. ELECTRIC POWER RESEARCH INSTITUTE, Chongqing (CN); CHONGQING UNIVERSITY, Chongqing (CN)

(72) Inventors: Xiyang OU, Chongqing (CN); Ran LIU, Chongqing (CN); Xingzhe HOU, Chongqing (CN); Ke ZHENG, Chongqing (CN); Zhihong FU, Chongqing (CN); Xiaorui HU, Chongqing (CN); Xiaoyong ZHANG, Chongqing (CN); Huaiqing ZHANG, Chongqing (CN); Jing JI, Chongqing (CN); Hua WU, Chongqing (CN); Hongliang SUN, Chongqing (CN)

(21) Appl. No.: 14/412,675

(22) PCT Filed: Mar. 4, 2014
(86) PCT No.: PCT/CN2014/072831

§ 371 Date: Jan. 3, 2015

(30) Foreign Application Priority Data
Dec. 16, 2013 (CN) 201310690114.9

(51) Int. Cl. G01R 23/16

(52) U.S. Cl. CPC G01R 23/16

(57) ABSTRACT

The application discloses a method for acquiring parameters of a dynamic signal, including: selecting a dynamic sample signal sequence of a power grid to constitute an autocorrelation matrix; determining an effective rank of the autocorrelation matrix and the number of frequency components of the dynamic sample signal sequence; establishing an AR model, and solving a model parameter of the AR model; determining an expression and a complex sequence of the dynamic sample signal sequence by using a Prony algorithm, wherein the dynamic sample signal sequence is represented by the complex sequence with a minimum square error; and substituting a root of a characteristic polynomial corresponding to the model parameter into the complex sequence and solving various parameters of the dynamic sample signal sequence. In the application, with the idea of AR parameter model, a current signal is considered to be a linear combination of signals at previous time points.

### FIELD

This application claims the priority to Chinese Patent Application No. 2013106901 14.9, entitled “METHOD FOR ACQUIRING PARAMETERS OF DYNAMIC SIGNAL”, filed on Dec. 16, 2013 with the Chinese State Intellectual Property Office, which is incorporated by reference in its entirety.

### BACKGROUND

As nonlinear devices such as power electronic devices are widely used in power systems, there are more and more harmonics and inter-harmonics, and there also exists damping oscillation components, which seriously affect the safe operation of the power systems. Analysis of harmonics, inter-harmonics and parameters of damping oscillation is important for the power systems.

The current harmonic analysis mainly uses the Fourier method, in which a signal is considered to be constituted by a series of sinusoidal frequency components without attenuation, thus it is unable to obtain damping oscillation parameters in a dynamic signal, and spectrum leakage and picket fence effect in Fourier analysis also cause a problem that inter-harmonics with similar frequencies cannot be detected. An Auto Regressive (AR) parameter spectrum estimation method can greatly improve the frequency resolution by establishing a parameter model to approximate to the real process, so it can be used in the inter-harmonic frequency analysis, but it can not obtain amplitude and phase of harmonics. In the Prony algorithm, a dynamic signal is considered to be constituted by a series of damped sinusoidal components having arbitrary amplitudes, phases, frequencies and attenuation factors, and thereby the Prony algorithm is particularly suitable to be used in the research of a non-stationary process having the damped oscillating components. Further, since a defect that the frequency resolution is limited by a window length in the Fourier analysis is overcome by applying a parametric model, thereby the Prony algorithm may also be used in an inter-harmonic detection. However, directly solving parameters such as amplitude, phase, frequency and attenuation factor in the Prony algorithm will result in solving a problem of a nonlinear least square, which has a greater difficulty and a poor numerical stability.

Therefore, it is urgent to obtain a solution for acquiring parameters of a dynamic signal in power grid harmonic analysis, which can quickly and accurately acquire the parameters of the dynamic signal in the power grid harmonics.

### SUMMARY

In view of this, the application provides a method for acquiring parameters of a dynamic signal to quickly and accurately acquire parameters of the dynamic signal in the power grid harmonics.

To achieve the above object, solutions are proposed as follows.

There is provided a method for acquiring parameters of a dynamic signal, including:

selecting a dynamic sample signal sequence of a power grid, and constituting an autocorrelation matrix by the dynamic sample signal sequence;

determining an effective rank of the autocorrelation matrix, and determining a number of frequency components of the dynamic sample signal sequence based on the effective rank;

establishing an AR model, and solving a model parameter of the AR model;

representing the dynamic sample signal sequence as a set of sinusoidal components of a damping oscillation by using a Prony algorithm;

determining a complex sequence of the dynamic sample signal sequence, wherein the dynamic sample signal sequence is represented by the complex sequence with a minimum square error; and

substituting a root of a characteristic polynomial corresponding to the model parameter into the complex sequence, and solving various parameters of the dynamic sample signal sequence, wherein the various parameters includes amplitude, phase, attenuation and frequency.

Preferably, an order Pₑ of the autocorrelation matrix satisfies the following formula: N/4<pₑ<N/3, wherein N is the number of sampling points.

Preferably, the process of determining the effective rank of the autocorrelation matrix and determining the number of frequency components of the dynamic sample signal sequence based on the effective rank includes:

decomposing the autocorrelation matrix by using a SVD method:

decomposing the autocorrelation matrix into: Rₑ=USV^{T}, wherein Rₑ is representative of the autocorrelation matrix, U is a pₑ×pₑ-dimensional orthogonal matrix, V is a (pₑ+1)×(pₑ+1)-dimensional orthogonal matrix, and S is a pₑ×(pₑ+1)-dimensional non-negative diagonal matrix;

taking a diagonal matrix Σₚ constituted by the first p singular values of the diagonal matrix S as the optimal approximation

$${\hat{R}}_{e} of {R}_{e} , {\hat{R}}_{e} = U {Σ}_{p} {V}^{T} = U [ \begin{matrix}{S}_{p} & 0 \\ 0 & 0\end{matrix} ] {V}^{T} ,$$

wherein Sₚ=diag(σ₁, σ₂, . . . , σₚ);

determining whether the dynamic sample signal sequence contains noise;

calculating βᵢ=σᵢ₊₁/σᵢ, 1≦i≦pₑ−1, determining i corresponding to a maximum βᵢ as an effective rank P, and determining the integer part of P/2 as the number P′ of frequency components, in the case that the dynamic sample signal sequence does not contain noise; and

determining the effective rank P based on a signal-to-noise ratio (SNR) and a local maximum value of βᵢ, and determining the integer part of P/2 as the number P′ of the frequency components, in the case that the dynamic sample signal sequence contains noise.

Preferably, the process of establishing the AR model includes:

representing the dynamic sample signal sequence as:

$$x ( n ) = - {\sum }_{k = 1}^{c} {a}_{k} x ( n - k ) + w ( n ) ,$$

wherein C is orders of the AR model, w(n) is a zero mean white noise sequence, aₖ is a model parameter of a C-order AR model.

Preferably, the process of solving the model parameter of the AR model includes:

determining whether the dynamic sample signal sequence contains noise;

taking the order C of the AR model as the effective rank P in the case that the dynamic sample signal sequence does not contain noise;

taking the order C of the AR model as the order Pₑ of the autocorrelation matrix in the case that the dynamic sample signal sequence contains noise; and

solving the model parameter aₖ by using a covariance algorithm.

Preferably, the process of representing the dynamic sample signal sequence as a set of sinusoidal components of a damping oscillation by using the Prony algorithm includes:

representing the dynamic sample signal sequence as:

$$x ( n ) = {\sum }_{i = 1}^{q} {A}_{i} {e}^{{α}_{i} {nT}_{s}} cos ( 2 π {f}_{i} {nT}_{s} + {θ}_{i} ) ,$$

wherein Tₛ is a sampling period, and q is the number of harmonics.

Preferably, the process of determining the complex sequence of the dynamic sample signal sequence includes:

representing the complex sequence as:

$$\hat{x} ( n ) = {\sum }_{m = 1}^{2 q} {b}_{m} {z}_{m}^{n} , n = 0 , 1 , … , N - 1 ,$$

wherein bₘ=Aₘ exp(jθₘ), zₘ=exp[(αₘ+j2πfₘ)Tₛ], and Aₘ, θₘ, αₘ, fₘ are parameters corresponding to amplitude, phase, attenuation and frequency respectively.

Preferably, the condition of the minimum square error is represented as:

$$min [ ɛ = {\sum }_{n = 0}^{N - 1} {\vert x ( n ) - \hat{x} ( n ) \vert}^{2} ]$$

Preferably, the process of substituting the root of the characteristic polynomial corresponding to the model parameter into the complex sequence and solving various parameters of the dynamic sample signal sequence includes:

constituting a characteristic polynomial by the model parameter aₖ, and solving a root zₖ of the characteristic polynomial, wherein zₖ corresponds to zₘ in the expression of the complex sequence;

substituting zₘ into the expression of the complex sequence, and determining a parameter bₘ by using the least square method; and

solving the various parameters of the dynamic sample signal sequence by the following expression:

$$\{ \begin{matrix}{A}_{m} = \vert {b}_{m} \vert \\ {θ}_{m} = {tan}^{- 1} [ Im ( {b}_{m} ) / Re ( {b}_{m} ) ] \\ {α}_{m} = ln \vert {z}_{m} \vert / {T}_{s} \\ {f}_{m} = {tan}^{- 1} [ Im ( {z}_{m} ) / Re ( {z}_{m} ) ] / 2 π {T}_{s}\end{matrix}$$

Preferably, after solving the various parameters of the dynamic sample signal sequence, the method further includes:

determining whether the number of frequency points is equal to the number P′ of the frequency components based on the result of the solving, and ending the process in the case that the number of frequency points is equal to the number P′ of the frequency components, otherwise selecting the first P′ components with larger magnitudes.

As can be seen from the above technical solutions, with the method for acquiring parameters of a dynamic signal of a power grid according to the embodiments of the application, firstly the number of frequency components of the dynamic signal is determined, then the model parameter of the dynamic signal is determined by using the AR method, and finally the parameters such as frequency, amplitude, phase, and attenuation of the dynamic signal are solved by using the Prony algorithm. In the application, with the idea of AR parameter model, a current signal is considered to be a linear combination of signals at previous time points, rather than directly solving parameters by the Prony algorithm, thus a nonlinear problem is transformed into a linear estimation problem, which makes the calculation process more simple and the calculation result more accurate.

### BRIEF DESCRIPTION OF THE DRAWINGS

In order to more clearly illustrate the technical solution in the embodiments of the application or in the conventional art, drawings to be used in the descriptions of the embodiments or the prior art will be introduced briefly hereinafter. Apparently, the drawings in the descriptions below are merely some embodiments of the application. Those skilled in the art can also obtain other drawings from these drawings without any creative efforts.

FIG. 1 is a flow chart of a method for acquiring parameters of a dynamic signal according to an embodiment of the application;

FIG. 2 is a flow chart of a method for determining the number of frequency components of the dynamic signal according to an embodiment of the application;

FIG. 3 is a flow chart of a method for determining the number of frequency components of the dynamic signal and AR model parameters of the dynamic signal according to an embodiment of the application;

FIG. 4 is a flow chart of another method for acquiring parameters of the dynamic signal according to an embodiment of the application; and

FIG. 5 is a flow chart of yet another method for acquiring parameters of the dynamic signal according to an embodiment of the application.

### DETAILED DESCRIPTION

The technical solution in the embodiments of the application will be described clearly and completely hereinafter in conjunction with the drawings in the embodiments of the application. Apparently, the embodiments described are merely some embodiments of the application, rather than all embodiments. All other embodiments that can be obtained by those skilled in the art based on the embodiments in the application without any creative efforts should fall within the scope of protection of the application.

### First Embodiment

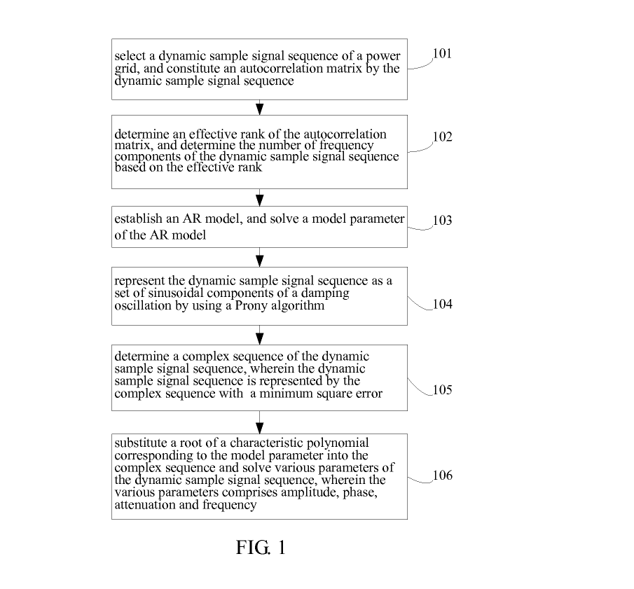

Reference is made to FIG. 1 which is a flow chart of a method for acquiring parameters of a dynamic signal according to an embodiment of the application.

As shown in FIG. 1, the method includes steps 101 to 106.

In step 101, a dynamic sample signal sequence of a power grid is selected to constitute an autocorrelation matrix.

Specifically, a sample signal sequence x(n) to be analyzed is selected, where the number of the sampling points is N, the order of the selected model is Pₑ, where N/4<pₑ<N/3 is satisfied, the order Pₑ may take any integer within this range. An autocorrelation matrix Rₑ is represented as:

$${R}_{e} = [ \begin{matrix}r ( 1 , 0 ) & r ( 1 , 1 ) & … & r ( 1 , {p}_{e} ) \\ r ( 2 , 0 ) & r ( 2 , 1 ) & … & r ( 2 , {p}_{e} ) \\ ⋮ & ⋮ & ⋮ & ⋮ \\ r ( {p}_{e} , 0 ) & r ( {p}_{e} , 1 ) & & r ( {p}_{e} , {p}_{e} )\end{matrix} ] \qquad ( 1 )$$

Each element r(i, j) is defined as:

$$r ( i , j ) = {\sum }_{n = {p}_{e}}^{N - 1} x ( n - j ) x ( n - i ) , \\ i , j = 0 , 1 , … , {p}_{e} \qquad ( 2 )$$

In step 102, an effective rank of the autocorrelation matrix is determined, and the number of frequency components of the dynamic sample signal sequence is determined based on the effective rank.

Specifically, the effective rank P of the matrix in the above equation (1) is calculated, and then the number of frequency components of the dynamic signal is determined based on the effective rank.

In step 103, an AR model is established, and a model parameter of the AR model is solved.

Specifically, it is assumed by the AR model that a signal x(n) is obtained by exciting an all-pole linear time-invariant discrete-time system by a zero mean white noise sequence w(n), i.e.,

$$x ( n ) = - {\sum }_{k = 1}^{C} {a}_{k} x ( n - k ) + w ( n ) ,$$

where C is the order of the model, w(n) is a zero mean white noise sequence, and aₖ is a model parameter of a C-order AR model. Then the model parameter of the AR model is solved.

In step 104, the dynamic sample signal sequence is represented as a set of sinusoidal components of a damping oscillation by the Prony algorithm.

Specifically, the dynamic sample signal sequence is represented as:

$$x ( n ) = {\sum }_{i = 1}^{q} {A}_{i} {e}^{{α}_{i} {nT}_{s}} cos ( 2 π {f}_{i} {nT}_{s} + {θ}_{i} ) ,$$

where Tₛ is a sampling period, and q is the number of harmonics.

In step 105, the complex sequence of the dynamic sample signal sequence is determined, and the dynamic sample signal sequence is represented by a complex sequence with a minimum square error.

In step 106, a root of a characteristic polynomial corresponding to the model parameter is substituted into the complex sequence, and various parameters of the dynamic sample signal sequence are solved, wherein the various parameters includes amplitude, phase, attenuation and frequency.

With the method for acquiring parameters of a dynamic signal of a power grid according to this embodiment of the application, firstly the number of frequency components of the dynamic signal is determined, then the model parameters of the dynamic signal are determined by using the AR method, and then the parameters such as frequency, amplitude, phase, and attenuation of the dynamic signal are solved by using the Prony algorithm. In the application, with the idea of AR parameter model, a current signal is considered to be a linear combination of signals at previous time points, rather than directly solving parameters in the Prony algorithm, thus a nonlinear problem is transformed into a linear estimation problem, which makes the calculation process more simple and the calculation result more accurate.

### Second Embodiment

In this embodiment, the process of determining the number of frequency components of the dynamic signal will be described in detail.

The autocorrelation matrix Rₑ has been determined in the first embodiment, and next the effective rank P of the matrix Rₑ may be determined by applying a SVD algorithm, and then the number of frequency components of the dynamic signal may be determined based on the effective rank P. Specifically, the autocorrelation matrix Rₑ is decomposed as:

Rₑ=USV^{T} (3)

where Rₑ is representative of the autocorrelation matrix, U is a pₑ×pₑ-dimensional orthogonal matrix, V is a (pₑ+1)×(pₑ+1)-dimensional orthogonal matrix, S is a pₑ×(pₑ+1)-dimensional non-negative diagonal matrix in which elements σₖₖ on the diagonal are singular values of the matrix Rₑ and satisfies σ₁₁≧σ₂₂≧ . . . ≧σₚ_{ₑ}_{,p}_{ₑ}≧0. It can be seen that the larger singular values of the matrix Rₑ are gathered on the front portion of the diagonal matrix S, therefore, a diagonal matrix Σₚ constituted by the first P singular values of the diagonal matrix S may be taken as the optimal approximation \hat{R}ₑ of Rₑ,

$${\hat{R}}_{e} = U {\sum }_{p} {V}^{T} = U [ \begin{matrix}{S}_{p} & 0 \\ 0 & 0\end{matrix} ] {V}^{T} , \\ Where \\ {S}_{p} = diag ( {σ}_{1} , {σ}_{2} , … , {σ}_{p} ) \qquad ( 4 )$$

The process of determining the effective rank P and the number of frequency components is described as follows.

It is determined whether the dynamic sample signal sequence contains noise. In the case that the signal x(n) does not contains noise, the first P singular values of the diagonal matrix S are significantly larger than the remaining singular values, and βᵢ=σᵢ₊₁/σᵢ, 1≦i≦pₑ−1 may be calculated, i corresponding to a maximum βᵢ is determined as the effective rank P, and the number P′ of the frequency components of the signal is an integer part of P/2. In the case that the signal x(n) contains noise, the effective rank P may be determined based on a signal-to-noise ratio (SNR) and a local maximum value of βᵢ, and the number P′ of the frequency components of the signal is an integer part of P/2.

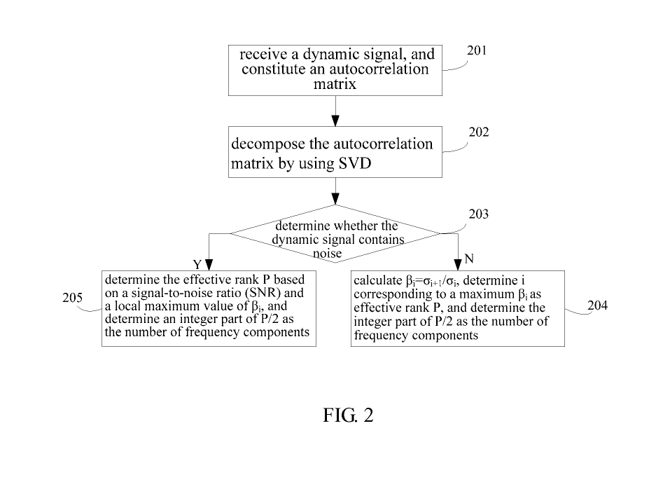

Reference is made to FIG. 2 which is a flow chart of a method for determining the number of frequency components of the dynamic signal according to an embodiment of the application.

The above process can be represented as the following steps:

step 201: receiving a dynamic signal, and constituting an autocorrelation matrix;

step 202: decomposing the autocorrelation matrix by using the SVD;

step 203: determining whether the dynamic signal contains noise;

step 204: in the case that the dynamic signal does not contain noise, calculating βᵢ=σᵢ₊₁/σᵢ, determining i corresponding to a maximum βᵢ as the effective rank P, and determining the integer part of P/2 as the number of frequency components; and

step 205: in the case that the dynamic signal contains noise, determining the effective rank P based on the signal-to-noise ratio (SNR) and a local maximum value of βᵢ, and determining an integer part of P/2 as the number of frequency component of the signal.

With the above process, the number of frequency components of the dynamical signal of the power grid can be determined.

In addition, the SVD method has a high frequency resolution even in a short sampling period, thereby the number of frequency components of the dynamic signal can be accurately determined, inter-harmonic components of the signal can be effectively distinguished, and also the difficulty in selecting the order of the AR model is overcame.

### Third Embodiment

In this embodiment, the process of determining a model parameter of the dynamic signal will be described in detail.

An AR model is established, by which it is assumed that a signal x(n) is obtained by exciting an all-pole point linear time-invariant discrete-time system by a zero mean white noise sequence w(n), i.e.,

$$x ( n ) = - {\sum }_{k = 1}^{C} {a}_{k} x ( n - k ) + w ( n ) \qquad ( 5 )$$

In the above formula, C is the order of the model, and aₖ is a model parameter of a C-order AR model.

For the effective rank P determined in the previous embodiment, for the signal which does not contain noise, the order of the AR model is taken as P; while for the signal which contains noise, the order of the AR model is needed to be greatly increased and may be taken as Pₑ. The model parameter aₖ may be obtained as {1, a₁, a₂ . . . aₚ} or {1, a₁, a₂, . . . aₚ_{ₑ}} by the covariance algorithm, which corresponds to the AR (P) model or the AR (Pₑ) model, respectively.

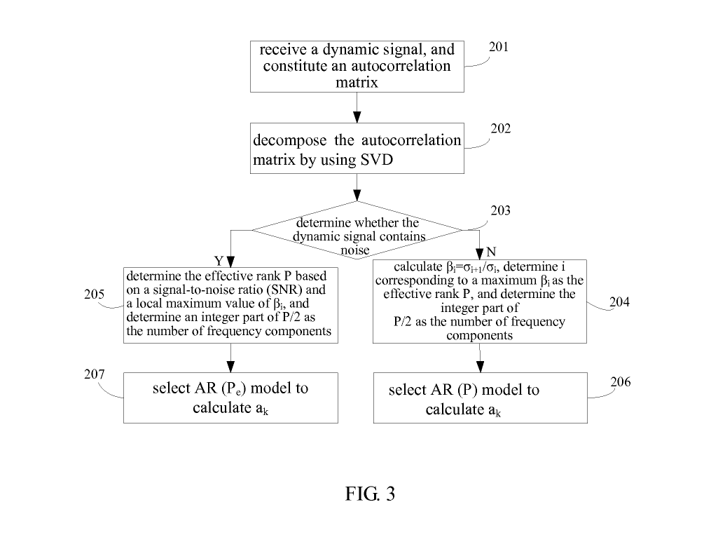

Reference is made to FIG. 3 which is a flow chart of a method for determining the number of frequency components of a dynamic signal and an AR model parameter of the dynamic signal according to an embodiment of the application.

After the step 205 of the second embodiment, the process further includes:

step 206: selecting the AR (P) model to calculate aₖ; and

step 207: selecting the AR (Pₑ) model to calculate aₖ.

### Fourth Embodiment

In this embodiment, the process of determining the parameters of the dynamic signal will be described in detail.

The Prony algorithm considers the signal x(n) as constituted by a set of sinusoidal components of a damping oscillation, i.e.,

$$x ( n ) = {\sum }_{i = 1}^{q} {A}_{i} {e}^{{α}_{i} {nT}_{s}} cos ( 2 π {f}_{i} {nT}_{s} + {θ}_{i} ) \qquad ( 6 )$$

where Tₛ is a sampling period, and q is the number of harmonics.

The dynamic signal x(n) may be represented by its complex sequence \hat{x}(n) with a minimum square error, and the complex sequence \hat{x}(n) is represented as:

$$\hat{x} ( n ) = {\sum }_{m = 1}^{2 q} {b}_{m} {z}_{m}^{n} , \\ n = 1 , 0 , … , N - 1 \qquad ( 7 )$$

where bₘ=Aₘ exp(jθₘ), zₘ=exp[(αₘ+j2πfₘ)Tₛ], Aₘ, θₘ, αₘ, fₘ are parameters corresponding to amplitude, phase, attenuation and frequency respectively.

The minimum square error is represented as:

$$min [ ɛ = {\sum }_{n = 0}^{N - 1} {\vert x ( n ) - \hat{x} ( n ) \vert}^{2} ] \qquad ( 8 )$$

As can be seen from the expression of \hat{x}(n), \hat{x}(n) is in the form of a homogeneous solution of a constant coefficient linear differential equation. Combining with the differential representation of x(n) in the formula (5) in the third embodiment, it can be seen that the AR model parameter aₖ derived in the third embodiment corresponds to a coefficient of the differential equation in the formula (7), and thus the root zₖ of the characteristic polynomial constituted by the model parameter aₖ corresponds to zₘ in the expression of the complex sequence. Next, by substituting the derived zₘ into the expression of \hat{x}(n) and applying the least square method, the parameter bₘ is determined, and the final calculation formula for Aₘ, θₘ, αₘ, fₘ can be given as follows:

$$\{ \begin{matrix}{A}_{m} = \vert {b}_{m} \vert \\ {θ}_{m} = {tan}^{- 1} [ Im ( {b}_{m} ) / Re ( {b}_{m} ) ] \\ {α}_{m} = ln \vert {z}_{m} \vert / {T}_{s} \\ {f}_{m} = {tan}^{- 1} [ Im ( {z}_{m} ) / Re ( {z}_{m} ) ] / 2 π {T}_{s}\end{matrix} \qquad ( 9 )$$

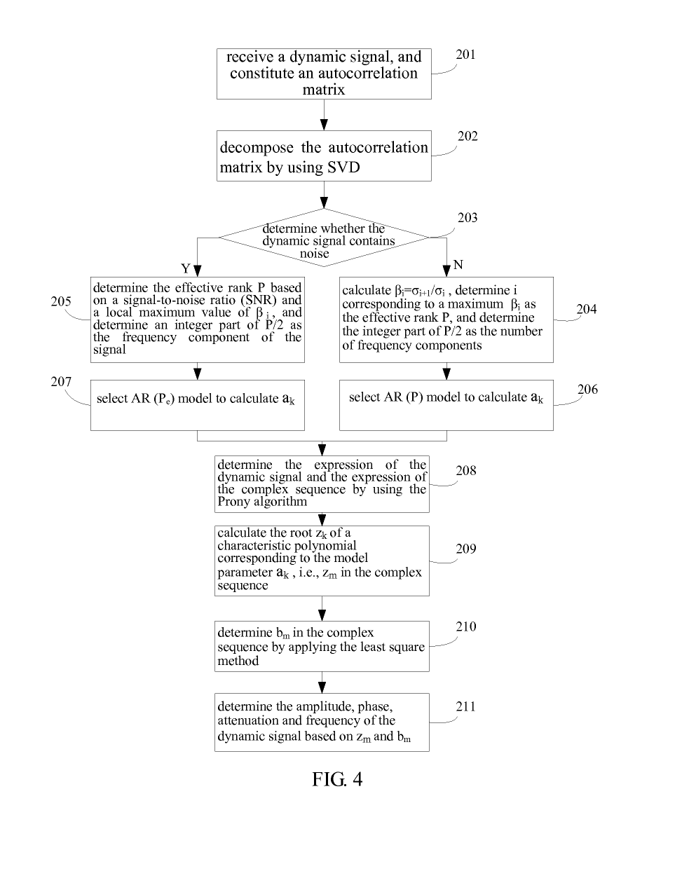

FIG. 4 is a flow chart of another method for acquiring parameters of the dynamic signal according to an embodiment of the application.

In addition to the steps in the previous embodiment, the present embodiment further includes:

step 208: determine the expression x(n) of the dynamic signal and the expression \hat{x}(n) of the complex sequence by using the Prony algorithm;

step 209: calculating the root zₖ of a characteristic polynomial corresponding to the model parameter aₖ, i.e., zₘ in the complex sequence \hat{x}(n);

step 210: determining bₘ in the complex sequence \hat{x}(n) by applying the least square method; and

step 211: determining the amplitude, phase, attenuation and frequency of the dynamic signals based on zₘ and bₘ.

By a combination of the AR method and the Prony algorithm, zₘ is obtained by using the AR method, and then the amplitude, phase, attenuation and frequency are determined by using the Prony algorithm, the limitation that only frequency information may be obtained by the AR method is overcome, and solving a problem of nonlinear least square is avoided when directly solving the Prony model.

### Fifth Embodiment

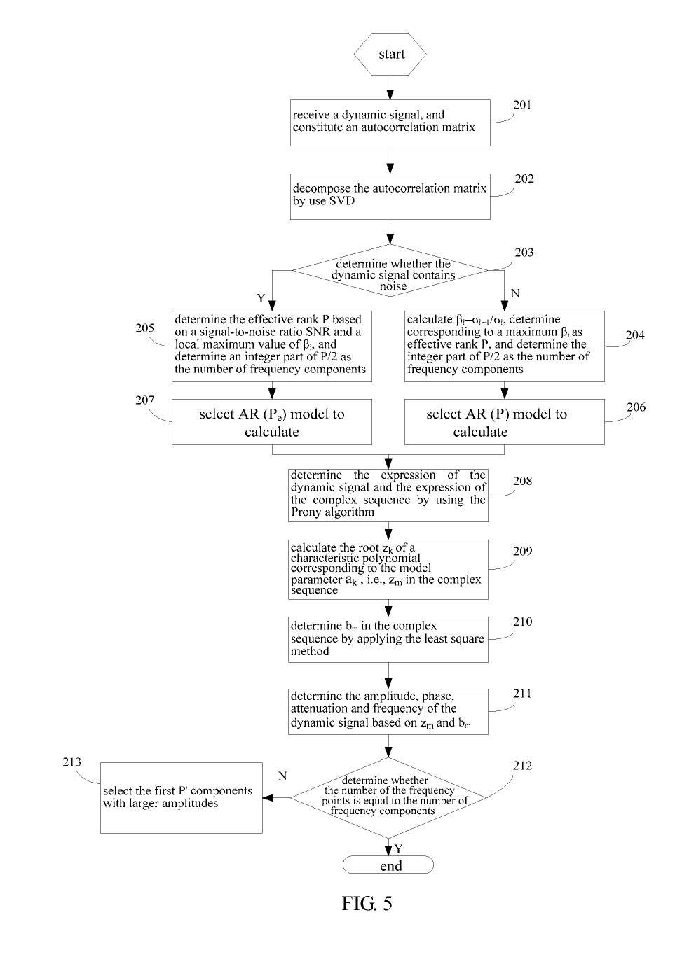

Reference is made to FIG. 5 which is a flow chart of yet another method for acquiring parameters of the dynamic signal according to an embodiment of the application.

There appears two cases when determining the model parameter aₖ, i.e., a noise case and a non-noise case. The order of the AR model is selected as Pₑ in the noise case, and the Pₑ is significantly greater than the number P′ of frequency components, i.e., P/2, therefore in the final calculated parameters, for the noise case, the number of the frequency points is certainly greater than P′, so the process of determining the number of the frequency points is added. That is, the process includes steps 212 and 213. In step 212, it is determined whether the number of the frequency points is equal to the number P′ of the frequency components. In step 213, if the number of the frequency points is not equal to the number P′ of the frequency components, the first P′ components with larger amplitudes are selected; if the number of the frequency points is equal to the number P′ of the frequency components, the process is ended. In this way, P′ parameters can be determined.

### Sixth Embodiment

In the present embodiment, the method for acquiring the parameters of the dynamic signal according to the embodiments of the application is compared with a conventional method which adopts the Prony algorithm.

### First Calculation Example

The power grid dynamic signal model is selected as follows:

x(t)=3 cos(2π×25t+π/5)+150 cos(2π×50t+π/4)+20 cos(2π×150t+π/6)+2 cos(2π×180t+π/3)+15 cos(2π×250t+π/8).

The calculation result obtained using the conventional Prony method and the calculation result obtained using the method according to the application, in the case of no noise and in the case of noise of 40 dB, are shown in the table 1, wherein frequency Fs=2000 Hz, sampling time is 0.04 s, the number of sampling points is 80.

TABLE 1

| | | No noise | | SNR = 40 | |
|---|---|---|---|---|---|
| | | Conventional | Method of the | Conventional | Method of the |
| Harmonic parameter | Actual value | Prony method | application | Prony method | application |
| Frequency 1/Hz | 25.0000 | 24.9511 | 24.9915 | 25.3191 | 25.1315 |
| Amplitude 1/V | 3.0000 | 2.9973 | 3.0001 | 3.0559 | 3.2923 |
| Phase 1/rad | 0.6283 | 0.6297 | 0.6284 | 0.6250 | 0.6292 |
| Frequency 2/Hz | 50.0000 | 50.2373 | 49.9936 | 50.0517 | 49.9972 |
| Amplitude 2/V | 150.0000 | 150.0688 | 149.9699 | 148.7885 | 149.9251 |
| Phase 2/rad | 0.7854 | 0.7850 | 0.7854 | 0.7907 | 0.7863 |
| Frequency 3/Hz | 150.0000 | 150.2105 | 149.9684 | 146.4531 | 150.0038 |
| Amplitude 3/V | 20.0000 | 19.9805 | 19.9997 | 20.1980 | 20.0062 |
| Phase 3/rad | 0.5236 | 0.5256 | 0.5236 | 0.5247 | 0.5236 |
| Frequency 4/Hz | 180.0000 | 180.3985 | 180.0494 | 180.4710 | 179.9445 |
| Amplitude 4/V | 2.0000 | 1.9951 | 2.0001 | 2.0243 | 2.0156 |
| Phase 4/rad | 1.0472 | 1.0458 | 1.0471 | 1.0443 | 1.0510 |
| Frequency 5/Hz | 250.0000 | 250.6705 | 250.0817 | 249.6672 | 249.9987 |
| Amplitude 5/V | 15.0000 | 15.0116 | 15.0025 | 14.8094 | 15.0016 |
| Phase 5/rad | 0.3927 | 0.3930 | 0.3927 | 0.3862 | 0.3931 |

### Second Calculation Example

The selected power grid dynamic signal model including inter-harmonics and attenuation components is as follows:

x(t)=150e^{-0.4πt} cos(2πf₁t+π/3)+10e^{-0.6πt} cos(2πf₂t+π/4)+2e^{-0.2πt} cos(2πf₃t+π/5).

The calculation result obtained using the conventional Prony method and the calculation result obtained using the method of the application in the case of no noise and in the case of noise of 40 dB, are shown in Table 2, wherein f1=50 Hz, f2=148 Hz, f3=245 Hz, the sampling frequency Fs=2000 Hz, the sampling time is 0.1 s, the number of sampling points is 200.

TABLE 2

| | | No noise | | SNR = 40 | |
|---|---|---|---|---|---|
| | | Conventional | Method of the | Conventional | Method of the |
| Harmonic parameter | Actual value | Prony method | application | Prony method | application |
| Frequency 1/Hz | 25.0000 | 24.9909 | 25.0028 | 25.4194 | 24.9540 |
| Amplitude 1/V | 3.0000 | 2.9851 | 3.0028 | 3.0599 | 2.9951 |
| Phase 1/rad | 0.6283 | 0.6260 | 0.6283 | 0.6327 | 0.6276 |
| attenuation | −1.2566 | −1.2564 | −1.2563 | −1.2394 | −1.2561 |
| Frequency 2/Hz | 50.0000 | 50.2471 | 50.0128 | 50.1815 | 50.0088 |
| Amplitude 2/V | 150.0000 | 149.5507 | 149.9101 | 149.1494 | 150.0344 |
| Phase 2/rad | 0.7854 | 0.7912 | 0.7854 | 0.7772 | 0.7844 |
| attenuation | −1.8850 | −1.8773 | −1.8854 | −1.8981 | −1.8863 |
| Frequency 3/Hz | 150.0000 | 150.4838 | 149.9778 | 150.7260 | 150.0640 |
| Amplitude 3/V | 20.0000 | 19.8690 | 19.9983 | 19.9612 | 20.0291 |
| Phase 3/rad | 0.5236 | 0.5213 | 0.5236 | 0.5216 | 0.5233 |
| attenuation | −0.6283 | −0.6268 | −0.6284 | −0.6227 | −0.6283 |

As seen from the comparison of Table 1 and Table 2, in the detection of harmonics, inter-harmonics and attenuation components, calculation accuracy can be greatly improved by applying the method according to the application, and the method has a better adaptability to the noise.

Further, it should be noted that, herein, relational terms such as “first” and “second” are only used to distinguish one entity or operation from another entity or operation, but do not necessarily require or imply that there is such actual relation or order among those entities and operations. Furthermore, the terms “including”, “containing”, or any other variations thereof are intended to cover a non-exclusive inclusion, so that a process, method, article or device including a series of elements includes not only these elements but also other elements which are not explicitly listed, or further includes inherent elements for such process, method, article or device. In the case there is no more restriction, the element defined by the statement “include(s) a . . . ” does not exclude the case that there is other same element in the process, method, article or device including the element.

The embodiments of the application are described herein in a progressive manner, with the emphasis of each of the embodiments on the difference between it and the other embodiments; hence, for the same or similar parts between the embodiments, one can refer to the other embodiments.

The above description of the disclosed embodiments makes the skilled in the art be capable of implementing or using the present application. Various modifications on those embodiments will be apparent for the skilled in the art. The general principle defined herein may be implemented in other embodiments without departing from the spirit or scope of the present application. Accordingly, the present application will not be limited by those embodiments illustrated herein, but will conform to the widest scope which is in accordance with the principle and novelty features discloses herein.

1. A method for acquiring parameters of a dynamic signal, comprising:
selecting a dynamic sample signal sequence of a power grid, and constituting an autocorrelation matrix by the dynamic sample signal sequence;
determining an effective rank of the autocorrelation matrix, and determining the number of frequency components of the dynamic sample signal sequence based on the effective rank;
establishing an AR model, and solving a model parameter of the AR model;
representing the dynamic sample signal sequence as a set of sinusoidal components of a damping oscillation by using a Prony algorithm;
determining a complex sequence of the dynamic sample signal sequence, wherein the dynamic sample signal sequence is represented by the complex sequence with a minimum square error; and
substituting a root of a characteristic polynomial corresponding to the model parameter into the complex sequence, and solving various parameters of the dynamic sample signal sequence, wherein the various parameters comprises amplitude, phase, attenuation and frequency.

2. The method according to claim 1, wherein an order Pₑ of the autocorrelation matrix satisfies the following formula: N/4<pₑ<N/3, wherein N is the number of sampling points.

3. The method according to claim 2, wherein the process of determining the effective rank of the autocorrelation matrix and determining the number of frequency components of the dynamic sample signal sequence based on the effective rank comprises:
decomposing the autocorrelation matrix by using a SVD method:
decomposing the autocorrelation matrix into: Rₑ=USV^{T}, wherein Rₑ is representative of the autocorrelation matrix, U is a pₑ×pₑ-dimensional orthogonal matrix, V is a (pₑ+1)×(pₑ+1)-dimensional orthogonal matrix, and S is a pₑ×(pₑ+1)-dimensional non-negative diagonal matrix;
taking a diagonal matrix Σₚ constituted by the first p singular values of the diagonal matrix S as the optimal approximation \hat{R}ₑ of Rₑ,
$${\hat{R}}_{e} = U {\sum }_{p} {V}^{T} = U [ \begin{matrix}{S}_{p} & 0 \\ 0 & 0\end{matrix} ] {V}^{T} , \qquad$$
wherein Sₚ=diag(σ₁, σ₂, . . . , σₚ);
determining whether the dynamic sample signal sequence contains noise;
calculating βᵢ=σᵢ₊₁/σᵢ, 1≦i≦pₑ−1, determining i corresponding to a maximum βᵢ as an effective rank P, and determining the integer part of P/2 as the number P′ of frequency components, in the case that the dynamic sample signal sequence does not contain noise; and
determining the effective rank P based on a signal-to-noise ratio SNR and a local maximum value of βᵢ, and determining the integer part P/2 as the number P′ of the frequency components, in the case that the dynamic sample signal sequence contains noise.

4. The method according to claim 3, wherein the process of establishing the AR model comprises:
representing the dynamic sample signal sequence as:
$$x ( n ) = - {\sum }_{k = 1}^{C} {a}_{k} x ( n - k ) + w ( n ) ,$$
wherein C is an order of the AR model, w(n) is a zero mean white noise sequence, aₖ is a model parameter of a C-order AR model.

5. The method according to claim 4, wherein the process of solving the model parameter of the AR model comprises:
determining whether the dynamic sample signal sequence contains noise;
taking the order C of the AR model as the effective rank P in the case that the dynamic sample signal sequence does not contain noise;
taking the order C of the AR model as the order Pₑ of the autocorrelation matrix in the case that the dynamic sample signal sequence contains noise; and
solving the model parameter aₖ by using a covariance algorithm.

6. The method according to claim 5, wherein the process of representing the dynamic sample signal sequence as a set of sinusoidal components of a damping oscillation by using the Prony algorithm comprises:
representing the dynamic sample signal sequence as:
$$x ( n ) = {\sum }_{i = 1}^{q} {A}_{i} {e}^{{α}_{i} {nT}_{s}} cos ( 2 π {f}_{i} {nT}_{s} + {θ}_{i} ) ,$$
wherein Tₛ is a sampling period, and q is the number of harmonics.

7. The method according to claim 6, wherein the process of determining the complex sequence of the dynamic sample signal sequence comprises:
representing the complex sequence as:
$$\hat{x} ( n ) = {\sum }_{m = 1}^{2 q} {b}_{m} {z}_{m}^{n} , \\ n = 1 , 0 , … , N - 1 ,$$
wherein bₘ=Aₘ exp(jθₘ), zₘ=exp[(αₘ+j2πfₘ)Tₛ], and Aₘ, θₘ, αₘ, fₘ are parameters corresponding to amplitude, phase, attenuation and frequency respectively.

8. The method according to claim 7, wherein the minimum square error is represented as:
$$min [ ɛ = {\sum }_{n = 0}^{N - 1} {\vert x ( n ) - \hat{x} ( n ) \vert}^{2} ] .$$

9. The method according to claim 8, wherein the process of substituting the root of the characteristic polynomial corresponding to the model parameter into the complex sequence and solving various parameters of the dynamic sample signal sequence comprises:
constituting a characteristic polynomial by the model parameter aₖ, and solving a root zₖ of the characteristic polynomial, wherein zₖ corresponds to zₘ in the expression of the complex sequence;
substituting zₘ into the expression of the complex sequence, and determining a parameter bₘ by using the least square method; and
solving the various parameters of the dynamic sample signal sequence by the following expression:
$$\{ \begin{matrix}{A}_{m} = \vert {b}_{m} \vert \\ {θ}_{m} = {tan}^{- 1} [ Im ( {b}_{m} ) / Re ( {b}_{m} ) ] \\ {α}_{m} = ln \vert {z}_{m} \vert / {T}_{s} \\ {f}_{m} = {tan}^{- 1} [ Im ( {z}_{m} ) / Re ( {z}_{m} ) ] / 2 π {T}_{s}\end{matrix} .$$

10. The method according to claim 9, wherein after solving the various parameters of the dynamic sample signal sequence, the method further comprises:
determining whether the number of frequency points is equal to the number P′ of the frequency components based on the result of the solving, and ending the process in the case that the number of frequency points is equal to the number P′ of the frequency components, otherwise selecting the first P′ components with larger magnitudes.
